(19) United States
(12) Patent Application Publication
(10) Pub. No.: US 2012/0262233 A1
(43) Pub. Date: Oct. 18, 2012

(54) MIXED SIGNAL DYNAMIC RANGE COMPRESSION

(75) Inventor: Maurice B. Richard, Gorham, ME (US)

(73) Assignee: Fairchild Semiconductor Corporation, San Jose, CA (US)

(21) Appl. No.: 13/445,590

(22) Filed: Apr. 12, 2012

Related U.S. Application Data
(60) Provisional application No. 61/476,023, filed on Apr. 15, 2011.

(51) Int. Cl. H03G 3/20

(52) U.S. Cl. 330/129

(57) ABSTRACT

This document discusses, among other things, apparatus and methods for providing dynamic range compression. In an example, an amplifier can an first amplifier configured to receive a representation of an input signal and provide an amplified representation of the input signal to an output stage, an automatic gain control comparator configured to provide automatic gain control information to the first amplifier, a plurality of dynamic range compression comparators configured to provide a plurality of signals indicative of an amplitude of an output signal of the output stage, a first voltage divider configured to provide an automatic gain control threshold to the automatic gain control comparator, and a second voltage divider configured to receive the automatic gain control threshold and to provide a plurality of range compression thresholds to the plurality of dynamic range compression comparators.

### CLAIM OF PRIORITY

This patent application claims the benefit of priority, under 35 U.S.C. Section 119(e), to Richard, U.S. Provisional Patent Application Ser. No. 61/476,023, entitled “MIXED SIGNAL DYNAMIC RANGE COMPRESSION,” filed on Apr. 15, 2011 (Attorney Docket No. 2921.128PRV), which is hereby incorporated by reference herein in its entirety.

### BACKGROUND

Dynamic range compression (DRC) is a technique that can be applied to a variety of signals to reduce a range of the processed signal. Such range reduction can be used, for example, in imaging to enhance higher frequency to low threshold details by reducing the range of lower frequency high threshold details. In audio applications, DRC can be used for the same purpose or to reduce the overall range, for example, narrowing the range between the high and low audio levels or volumes of an audio signal as the input levels of the audio signal extends past a threshold. DRC techniques can be implemented in various ways. For mobile applications, speed, size, and power draw are some of the factors that can compete to define a desirable implementation.

### Overview

This document discusses, among other things, apparatus and methods for providing dynamic range compression. In an example, an amplifier can include a first amplifier configured to receive a representation of an input signal and provide an amplified representation of the input signal to an output stage, an automatic gain control comparator configured to provide automatic gain control information to the first amplifier, a plurality of dynamic range compression comparators configured to provide a plurality of signals indicative of an amplitude of an output signal of the output stage, a first voltage divider configured to provide an automatic gain control threshold to the automatic gain control comparator, and a second voltage divider configured to receive the automatic gain control threshold and to provide a plurality of range compression thresholds to the plurality of dynamic range compression comparators.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example DRC circuit in an audio system.

FIG. 2 illustrates generally a flowchart of an example method of dynamic range compression.

FIG. 3 illustrates generally a comparison of continuous ideal audio output voltage and gain, and actual piecewise linearly approximated audio output voltage and gain using an example DRC function.

FIG. 4 illustrates generally simulation plots of a system employing an example of a DRC function.

### DETAILED DESCRIPTION

The present inventor has recognized, among other things, a DRC function that can be implemented with minimal analog circuitry, in certain examples, without substantial increase in die area or substantial additional power, when compared with compression techniques implemented in a digital signal processor (DSP), for example. In certain examples, the DRC function can use digital logic, running at relatively low clock speeds, to approximate a DRC transfer curve. In an example, the digital logic gate count can be substantially smaller than a DSP implementation.

In certain examples, such as mobile systems, analog circuitry of the DRC circuit can use components already implemented for automatic gain control (AGC) or power limiting, further reducing the amount of additional circuitry or design effort, as well as providing the DRC functions while using little if any additional power.

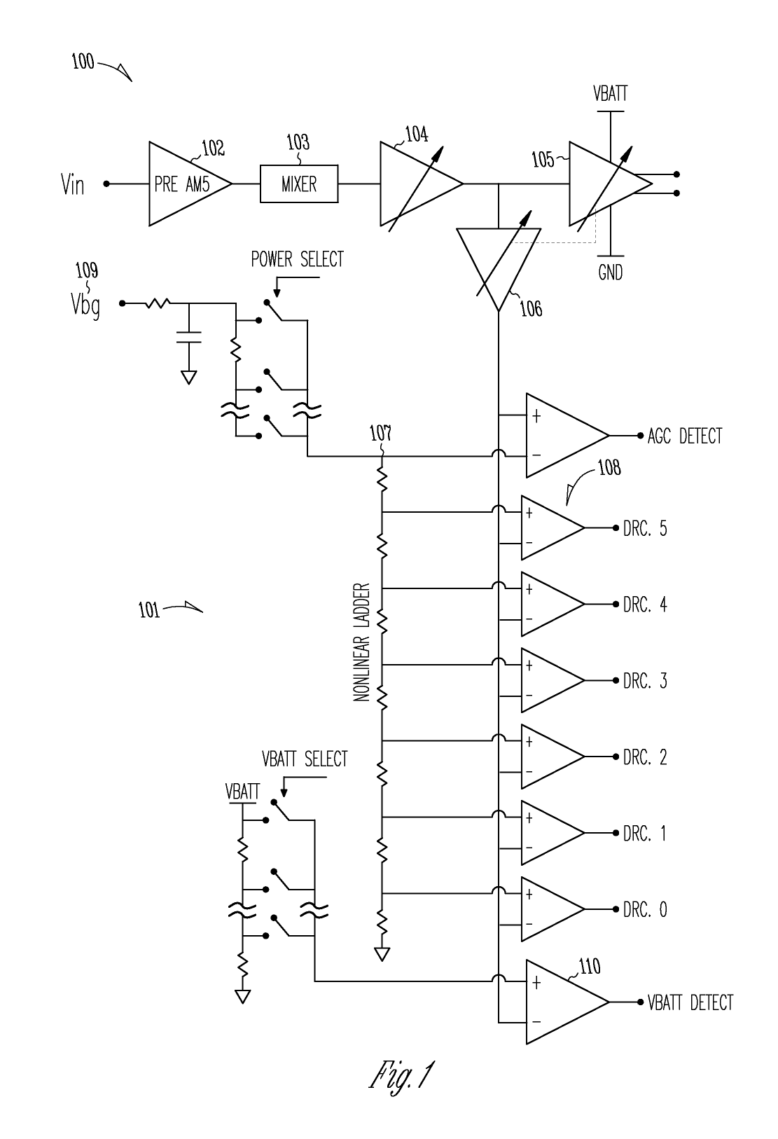

FIG. 1 illustrates generally an example of a DRC circuit 101 in an audio system 100. The audio system 100 can include a preamplifier 102, a mixer 103, a volume controller or attenuator 104, and a driver 105. The pre amplifier 102 and mixer 103 can process one or more received audio signal (Vin) to provide a desired processed audio signal. The attenuator 104 can allow adjustment of the volume of the processed audio signal and the driver 105 can amplify the processed audio signal to drive a transducer such as a speaker.

As the range of the audio signal expands, it can be desirable to limit the expansion of the range. In an example, the range can be limited to prevent saturation of components of the audio system. In an example, the range can be limited to minimize washing out smaller ranged details of the signal. In an example, the driver 105 can be adjustable to compress a range of the processed audio signal. In certain examples, the output of the attenuator 104 can be used to provide information about the output of the drive amplifier including information about the anticipated range of the output signal of an output stage of the drive amplifier, such as a D-class amplifier, for example.

In an example, a representation of the output signal of the drive amplifier can be provided using a sampling device 106, such as a sampling amplifier or a half wave rectifier. In an example, the sampling device 106 can be adjustable and the adjustment of the sampling device 106 can be coordinated with adjustment of the driver 105 such that a gain of the sampling device tracks the gain of the driver 105. In other examples, the sampling device 106 and the driver 105 are not adjustable.

The representation of the output of the driver 105, the sample signal, can be provided to and received by a DRC circuit 101 configured to assist in the DRC function. In an example, the DRC circuit 101 can include a voltage divider, such as a resistor ladder 107, and a plurality of DRC comparators 108. Each DRC comparator 108 can include a first input coupled to the sampled signal and a second input coupled to a tap of the resistor ladder 107. As the level of the sample signal increases, outputs of the DRC comparators 108 can change state. The outputs of the plurality of DRC comparators 108 can be received by a processor of an electrical device, such as a baseband processor of mobile cell phone, for example. The processor can execute an algorithm to modulate the compression of the processed audio signal using the outputs of the plurality of comparators 108, for example, by adjusting the gain of the attenuator 104.

In an example, the outputs of the DRC comparators 108 can be used to provide a piecewise linear approximation of a continuous DRC function. In certain examples, a piecewise linear approximation can provide excellent audio quality such that artifacts of the approximation are very subtle and in many cases unnoticeable to the casual listener. In an example, the resistor ladder 107 can set a threshold for each of the DRC comparators 108. In certain examples, the resistor ladder 107 is non-linear. In an example, a voltage reference such as a band-gap voltage 109 can be applied to the resistor ladder to set each of the DRC comparator thresholds. In an example, a power threshold can be used to modify the thresholds of the DRC comparators 108 as well as a threshold for detecting a change in the automatic gain control (AGC). In an example, a comparator 110 can compare the sampled attenuator output signal to a battery threshold to modulate the performance of the audio system 100. In an example, the gain of the sampling device 106 can be about 6 db lower than the gain of the driver 105. In certain examples, the gain of the driver can 105 can be selectable and can include selections for 10 db, 16 db, and 24 db. It is understood that other values of gain for the driver are possible without departing from the scope of the present subject matter. In an example, the a range of gain for the attenuator 104 can be about 0 to about −60 db, however other values of gain are possible without departing from the scope of the present subject matter.

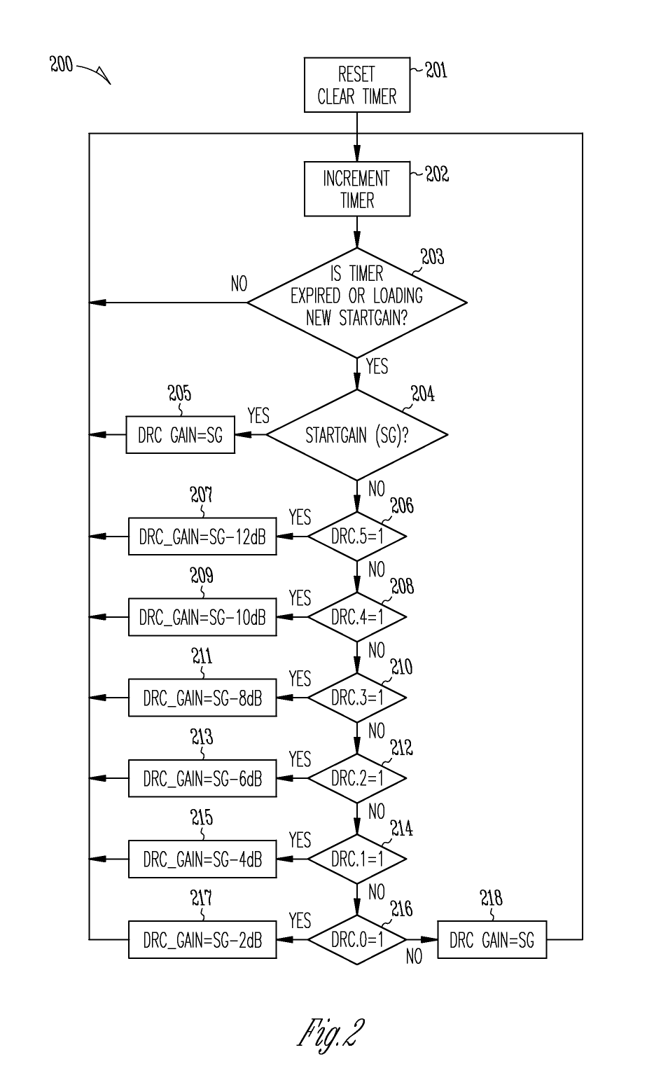

FIG. 2 illustrates generally a flowchart of an example method 200 of dynamic range compression. At step 201, a DRC timer is cleared. At step 202, the DRC timer is incremented.

At step 203, the DRC timer can be evaluated as to whether it has expired or whether a new start gain has been established. If neither the DRC timer is expired nor a new start gain has been established, the method 200 can loop to increment the DRC timer at step 202. If a new start gain has been established and detected at step 204, then, at step 205, the DRC gain can be set to the new gain and the method 200 can loop to increment the DRC timer at step 202. If the DRC timer has expired, the DRC comparators can be evaluated and the DRC gain can be adjusted accordingly.

For example, at step 206, if the output of a sixth DRC comparator is detected as active, then, at step 207, the DRC gain can be set to the start gain minus 12 db. The method 200 can loop to increment the DRC timer each time a new DRC gain is set. At step 208, if the output of a fifth DRC comparator is detected as active, then, at step 209, the DRC gain can be set to the start gain minus 10 db. At step 210, if the output of a fourth DRC comparator is detected as active, then, at step 211, the DRC gain can be set to the start gain minus 8 db. At step 212, if the output of a third DRC comparator is detected as active, then, at step 213, the DRC gain can be set to the start gain minus 6 db. At step 214, if the output of a second DRC comparator is detected as active, then, at step 215, the DRC gain can be set to the start gain minus 4 db. At step 216, ifthe output of a first DRC comparator is detected as active, then, at step 217, the DRC gain can be set to the start gain minus 2 db. If the outputs of the DRC comparators are not active, the DRC gain can be set to the start gain at step 218. It is understood that other values for the DRC gain, and more or less DRC comparators, are possible without departing from the scope of the present subject matter.

In certain embodiments, gain changes can be ramped, for example, instead of jumping from a DRC gain of the start gain minus 12 db to the start gain in one interval, the gain can progress to the start gain over several intervals, for example, at each DRC gain defined by the comparators.

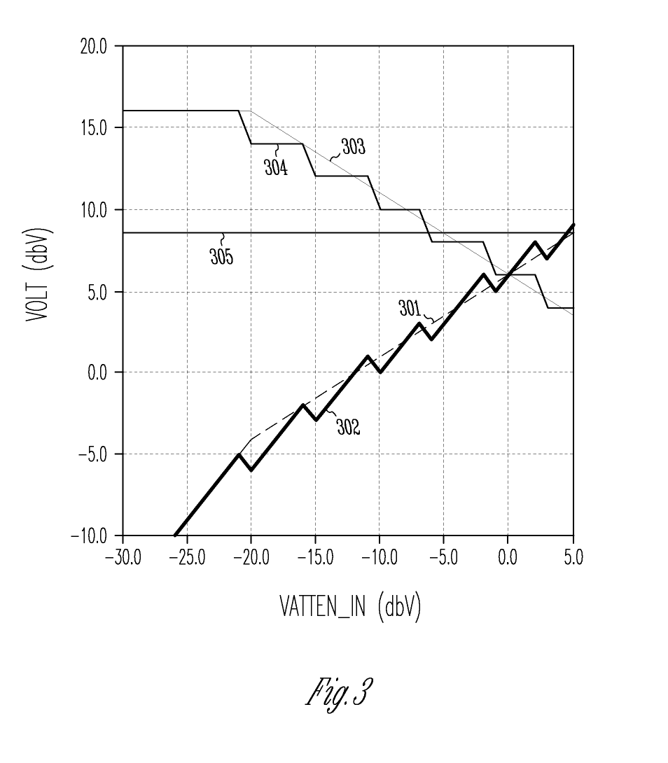

FIG. 3 illustrates generally a continuous audio output voltage 301 and actual piecewise linearly approximated audio output voltage 302 using a DRC function as described above. FIG. 3 also illustrates generally a comparison of continuous audio system gain 303 and actual piecewise linearly approximated audio system gain 304 using a DRC function as described above. An example AGC limit 305 is also shown in the plot of FIG. 3.

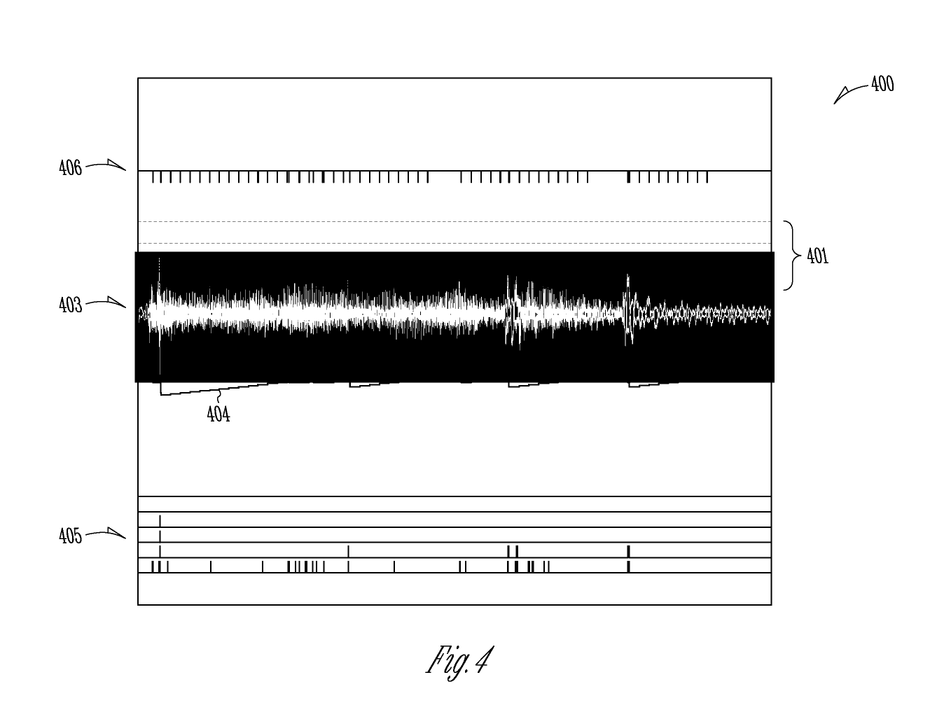

FIG. 4 illustrates generally simulation plots 400 of a system employing an example DRC function. FIG. 4 includes reference lines indicating the threshold levels 401 associated with the DRC comparators (DRC.0, DRC.1, . . . , DRC.n). Imposed on the reference lines is output of the attenuator 403.

FIG. 4 also plots the gain 404 of the audio system and the outputs 405 of the DRC comparators (DRC.0, DRC.1, . . . , DRC.n). The gain changes as the outputs of the DRC comparators indicate that the processed audio signal exceed certain DRC thresholds levels 401. The illustrated simulation includes a plot of a release timer output 406. In certain examples, a release timer can be enabled whenever the gain 404 of the audio system has been lowered due to the DRC circuit. In certain examples, when the release timer completes, the gain 404 of the audio system can be increased by a predetermined amount. In an example, the gain 404 can be increased via the expiration of the release timer until the gain reaches a predetermined gain setting 407 for the system or until the gain 404 is lowered because the audio signal exceeds a DRC threshold 401.

### Additional Notes & Examples

In Example 1, an amplifier circuit can include a first amplifier configured to receive a representation of an input signal and provide an amplified representation of the input signal to an output stage, an automatic gain control comparator configured to provide automatic gain control information to the first amplifier, a plurality of dynamic range compression comparators configured to provide a plurality of signals indicative of an amplitude of an output signal of the output stage, a first voltage divider configured to provide an automatic gain control threshold to the automatic gain control comparator, an a second voltage divider configured to receive the automatic gain control threshold and to provide a plurality of range compression thresholds to the plurality of dynamic range compression comparators.

In Example 2, the amplifier circuit of Example 1 optionally includes a preamplifier configured to receive the input signal and to provide the representation of the input signal to the first amplifier.

In Example 3, the amplifier circuit of any one or momre of Examples 1-2 optionally includes a second amplifier coupled to an output of the first amplifier, the second amplifier configured to provide a representation of an output of the amplifier circuit to the automatic gain comparator.

In Example 4 the second amplifier of any one or more of Examples 1-3 optionally is configured to provide a representation of the output of the amplifier circuit to the plurality of dynamic range compression comparators.

In Example 5,the amplifier circuit of any one or more of Examples 1-4 optionally includes the output stage.

In Example 6, the output stage of any one or more of Examples 1-5 optionally includes a D-class amplifier.

In Example 7, the output stage of any one or more of Examples 1-6 optionally includes an adjustable gain.

In Example 8, a gain of the second amplifier of any one or more of Examples 1-7 optionally is configured to track the gain of the output stage.

In Example 9, the first voltage divider of any one or more of Examples 1-8 optionally includes a plurality of non-linear taps.

In Example 10, the second voltage divider of any one or more of Examples 1-9 optionally includes a plurality of non-linear taps configured to provide the plurality of range compression thresholds.

In Example 11, the amplifier circuit of any one or more of Examples 1-10 optionally includes a state machine configured to modulate a gain of the first amplifier based on the plurality of signals indicative of the amplitude of the output signal of the output stage.

In Example 12, a method can include providing an amplified representation of an input signal to an output stage of an amplifier circuit using an amplifier, providing automatic gain control information to the amplifier using an automatic gain control comparator, providing a plurality of signals indicative of an amplitude of an output signal of the output stage using a plurality of dynamic range compression comparators, providing an automatic gain control threshold to the automatic gain comparator using a first voltage divider, receiving the automatic gain control threshold at a second voltage divider, and providing a plurality of range compression thresholds to the plurality of dynamic range compression comparators using the second voltage divider.

In Example 13, the method of any one or more of Examples 1-12 optionally includes preamplifying the input signal, and providing the preamplified input signal to the amplifier.

In Example 14, the method of any one or more of Examples 1-13 optionally includes providing a representation of an output of the amplifier to the automatic gain comparator using a sampling amplifier.

In Example 15, the method of any one or more of Examples 1-14 optionally includes providing the representation of the output of the amplifier to the plurality of dynamic range compression comparators.

In Example 16, the providing the automatic gain control threshold of any one or more of Examples 1-15 optionally includes selecting one of a plurality of taps of the first voltage divider to provide the automatic gain control threshold to the the automatic gain comparator.

In Example 17, the providing the automatic gain control threshold of any one or more of Examples 1-16 optionally includes selecting one of a plurality of non-linear taps of the first voltage divider to provide the automatic gain control threshold to the automatic gain comparator.

In Example 18, the providing a plurality of range compression thresholds of any one or more of Examples 1-17 optionally includes receiving, from one of a plurality of taps of the second voltage divider, at each of the plurality dynamic range compression comparators one of the plurality of range compression thresholds.

In Example 19, the providing a plurality of range compression thresholds of any one or more of Examples 1-18 optionally includes receiving, from one of a plurality of non-linear taps of the second voltage divider, at each of the plurality dynamic range compression comparators one of the plurality of range compression thresholds.

In Example 20, the providing the automatic gain threshold of any one or more of Examples 1-19 optionally includes receiving a band-gap reference voltage at the first voltage divider.

In Example 21, the method of any one or more of Examples 1-20 optionally includes receiving, at a state machine, the plurality of signals indicative of an amplitude of the output signal from the plurality of dynamic range compression comparators, and modulating a gain of the amplifier in response to the plurality of signals, wherein modulating the gain includes using an output of the state machine.

In Example 22, a system or method can include, or can optionally be combined with any portion or combination of any portions of any one or more of Examples 1-21 to include, subject matter that can include means for performing any one or more of the functions of Examples 1-21, or a machine-readable medium including instructions that, when performed by a machine, cause the machine to perform any one or more of the functions of Examples 1-21.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. An amplifier circuit comprising:
a first amplifier configured to receive a representation of an input signal and provide an amplified representation of the input signal to an output stage;
an automatic gain control comparator configured to provide automatic gain control information to the first amplifier;
a plurality of dynamic range compression comparators configured to provide a plurality of signals indicative of an amplitude of an output signal of the output stage;
a first voltage divider configured to provide an automatic gain control threshold to the automatic gain control comparator; and
a second voltage divider configured to receive the automatic gain control threshold and to provide a plurality of range compression thresholds to the plurality of dynamic range compression comparators.

2. The amplifier circuit of claim 1, including a preamplifier configured to receive the input signal and to provide the representation of the input signal to the first amplifier.

3. The amplifier circuit of claim 1, including a second amplifier coupled to an output of the first amplifier, the second amplifier configured to provide a representation of an output of the amplifier circuit to the automatic gain comparator.

4. The amplifier circuit of claim 3, wherein the second amplifier is configured to provide a representation of the output of the amplifier circuit to the plurality of dynamic range compression comparators.

5. The amplifier circuit of claim 3, including the output stage.

6. The amplifier circuit of claim 5, wherein the output stage includes a D-class amplifier.

7. The amplifier circuit of claim 5, wherein the output stage includes an adjustable gain.

8. The amplifier circuit of claim 7, wherein a gain of the second amplifier is configured to track the gain of the output stage.

9. The amplifier circuit of claim 1, wherein the first voltage divider includes a plurality of non-linear taps.

10. The amplifier circuit of claim 1, wherein the second voltage divider includes a plurality of non-linear taps configured to provide the plurality of range compression thresholds.

11. The amplifier circuit of claim 1, including a state machine configured to modulate a gain of the first amplifier based on the plurality of signals indicative of the amplitude of the output signal of the output stage.

12. A method comprising:
providing an amplified representation of an input signal to an output stage of an amplifier circuit using an amplifier;
providing automatic gain control information to the amplifier using an automatic gain control comparator;
providing a plurality of signals indicative of an amplitude of an output signal of the output stage using a plurality of dynamic range compression comparators;
providing an automatic gain control threshold to the automatic gain comparator using a first voltage divider;
receiving the automatic gain control threshold at a second voltage divider; and
providing a plurality of range compression thresholds to the plurality of dynamic range compression comparators using the second voltage divider.

13. The method of claim 12, including:
preamplifying the input signal; and
providing the preamplified input signal to the amplifier.

14. The method of claim 12, including providing a representation of an output of the amplifier to the automatic gain comparator using a sampling amplifier.

15. The method of claim 13, including providing the representation of the output of the amplifier to the plurality of dynamic range compression comparators.

16. The method of claim 12, wherein the providing the automatic gain control threshold includes selecting one of a plurality of taps of the first voltage divider to provide the automatic gain control threshold to the the automatic gain comparator.

17. The method of claim 16, wherein the providing the automatic gain control threshold includes selecting one of a plurality of non-linear taps of the first voltage divider to provide the automatic gain control threshold to the automatic gain comparator.

18. The method of claim 12, wherein the providing a plurality of range compression thresholds includes receiving, from one of a plurality of taps of the second voltage divider, at each of the plurality dynamic range compression comparators one of the plurality of range compression thresholds.

19. The method of claim 18, wherein the providing a plurality of range compression thresholds includes receiving, from one of a plurality of non-linear taps of the second voltage divider, at each of the plurality dynamic range compression comparators one of the plurality of range compression thresholds.

20. The method of claim 12, wherein providing the automatic gain threshold includes receiving a band-gap reference voltage at the first voltage divider.

21. The method of claim 12, including
receiving, at a state machine, the plurality of signals indicative of an amplitude of the output signal from the plurality of dynamic range compression comparators; and
modulating a gain of the amplifier in response to the plurality of signals, wherein modulating the gain includes using an output of the state machine.
